(19) United States
(12) Patent Application Publication
(10) Pub. No.: US 2025/0147426 A1
(43) Pub. Date: May 8, 2025

(54) FACET MIRROR ASSEMBLY

(71) Applicant: Carl Zeiss SMT GmbH, Oberkochen (DE)

(72) Inventor: Ralf AMELING, Aalen (DE)

(21) Appl. No.: 19/017,878

(22) Filed: Jan. 13, 2025

Related U.S. Application Data
(63) Continuation of application No. PCT/EP2023/069935, filed on Jul. 18, 2023.

(30) Foreign Application Priority Data
Jul. 25, 2022 (DE) 10 2022 207 546.3

(51) Int. Cl. G03F 7/00; G02B 5/09

(52) U.S. Cl. CPC G03F 7/70075; G02B 5/09; G03F 7/702; G03F 7/70316; G03F 7/70833

(57) ABSTRACT

A facet mirror assembly has a carrier body for a plurality of individual mirrors. Reflection surfaces of the individual mirrors are individually tiltable, via assigned tilt actuators, about at least one tilt axis within an individual mirror tilt angle range around a neutral tilt position between a maximum angle and a minimum angle. The individual mirrors have at least two different neutral tilt positions in a range around a mean value of a total tilt angle range. The result can be a facet mirror assembly having improved properties with respect to a tilt actuator system of the facet mirror assembly.

### CROSS-REFERENCE TO RELATED APPLICATIONS

The present application is a continuation of, and claims benefit under 35 USC 120 to, international application No. PCT/EP2023/069935, filed Jul. 18, 2023, which claims benefit under 35 USC 119 of German Application No. 10 2022 207 546.3, filed Jul. 25, 2022. The entire disclosure of each of these applications is incorporated by reference herein.

### FIELD

The disclosure relates to a facet mirror assembly. Furthermore, the disclosure relates to an illumination optical unit for projection lithography comprising such a facet mirror, an optical system comprising such an illumination optical unit, a projection exposure apparatus comprising such an optical system, a method for producing a microstructured or nanostructured component, and a component produced by the method.

### BACKGROUND

A facet mirror assembly is known from DE 10 2018 207 103 A1. Illumination optical units for projection lithography are known from U.S. Pat. No. 9,977,335, WO 2009/100856 A1 and WO 2008/011981 A1.

### SUMMARY

The present disclosure seeks to provide a facet mirror assembly having desirable properties with respect to a tilt actuator system of the facet mirror assembly.

In an aspect, the disclosure provides a facet mirror assembly comprising a carrier body for a plurality of individual mirrors. Reflection surfaces of the individual mirrors are individually tiltable, via assigned tilt actuators, about at least one tilt axis within an individual mirror tilt angle range around a neutral tilt position between a maximum angle and a minimum angle. The individual mirrors have at least two different neutral tilt positions in a range around a mean value of a total tilt angle range. The facet mirror assembly can have a MEMS setup.

A facet mirror assembly according to the disclosure can help make it possible to have a large total tilt angle range covered by the totality of the individual mirrors, with smaller individual mirror tilt angle ranges of the respective individual mirrors in comparison with the total tilt angle range. On account of the different neutral tilt positions, the larger total tilt angle range can be covered by way of different, respectively shifted individual mirror tilt angle ranges which result on account of the different neutral tilt positions. This can help make it possible to use a tilt actuator system for the individual mirrors which, on account of the desired smaller tilt angle range, can be designed in a manner adapted to other desired properties with respect to the facet mirror assembly, in particular with regard to a good thermal conductivity between the reflection surfaces of the individual mirrors and the carrier body of the facet mirror assembly. Accordingly, the smaller individual mirror tilt angle range in comparison with the total tilt angle range can help make it possible to reduce a surface temperature of the reflection surfaces of the individual mirrors for the case where during the reflection by the individual mirrors a residual absorption of reflected light occurs, which is the case for example when the facet mirror assembly is used during the reflection of EUV light.

Substrate bodies of the individual mirrors can be fixed to the carrier body of the facet mirror assembly. The facet mirror assembly can have a MEMS setup that is described for example in DE 10 2008 009 600 A1.

Individual mirrors assigned to the carrier body can then have different neutral tilt positions if, from among these individual mirrors, specific individual mirrors have one neutral tilt position and other individual mirrors have a neutral tilt position which is different therefrom.

The facet mirror assembly can have a plurality of carrying bodies. Individual mirrors of the facet mirror assembly which are assigned to at least one of the plurality of carrying bodies and the substrate bodies of which are then fixed to this carrying body each can have at least two different neutral tilt positions. More than two different neutral tilt positions of the individual mirrors which are fixed to the same carrying body of the facet mirror assembly are also possible, for example three, four, five or even more neutral tilt positions. In the limiting case, each of the individual mirrors fixed to the same carrier body of the facet mirror assembly can have an individual neutral tilt position.

The reflection surfaces of the individual mirrors can be individually tiltable, via the assigned actuators, about two tilt axes within a respective tilt angle range around a neutral tilt position between a maximum angle and a minimum angle, wherein, for predefining the respective tilt angle ranges around each of the two tilt axes, the individual mirrors have at least two different neutral tilt positions in a range around a mean value of a total tilt angle range around the respective tilt axis. In this case, the concept of the smaller individual mirror tilt angle range in comparison with the total tilt angle range is applied to the two tilt angle dimensions around the two tilt axes. Corresponding features can be afforded in both tilt angle dimensions.

A plurality of groups can comprise facet mirrors within each case the same group neutral tilt position. Such an individual mirror grouping can simplify a setup of the facet mirror assembly. Such an individual mirror group can be embodied as a row or a column, i.e. as a 1D group, or as an array comprising at least two rows and at least two columns, i.e. as a 2D group. The facet mirror assembly can have a plurality of groups of such individual mirrors each having the same group neutral tilt position, wherein the group neutral tilt positions of at least two of these groups which are each fixed to the same carrying body of the facet mirror assembly are different from one another. In addition, individual mirrors in such a facet mirror assembly having individual neutral tilt positions can be provided which are fixed to the same carrying body of the facet mirror assembly as the individual mirror groups.

The magnitude of the total tilt angle range can be at least 1.1 times that of the individual mirror tilt angle range. Such a tilt angle range ratio has proved to be suitable in practice for making possible, on the one hand, the desired properties with respect to the tiltability of the individual mirrors and, on the other hand, a reduction of the desired properties with respect to a mechanical system and actuator system on account of the smaller individual mirror tilt angle range. The ratio between the total tilt angle range and the individual mirror tilt angle range can be of the order of 1.2, can be of the order of 1.5, can be 2 or greater, and is regularly less than 100.

Each of the individual mirrors can have a mirror plate and a substrate body, wherein the respective tilt actuator of the individual mirror is arranged between the mirror plate and the substrate body, and wherein the respective neutral tilt position of one of the individual mirrors is predefined by way of a corresponding wedge shape of a wedge connecting section of the substrate body of this individual mirror. Such a configuration can help make possible a neutral tilt position predefinition by way of a corresponding wedge shape of the substrate body for the respective individual mirror. Individual mirrors constructed identically otherwise can be used in this variant. This can reduce the production outlay for the facet mirror assembly. The substrate body can also be two-dimensionally wedge-shaped in order to predefine respective neutral tilt positions around two tilt axes of the respective individual mirror.

Each of the individual mirrors can have a mirror plate and a substrate body, wherein the respective tilt actuator of the individual mirror is arranged between the mirror plate and the substrate body, and wherein the respective neutral tilt position of one of the individual mirrors is predefined by way of a corresponding wedge shape of the mirror plate of this individual mirror. By way of such a configuration, different neutral tilt positions can likewise be predefined for the individual mirrors. Accordingly, the design of a two-dimensionally wedge-shaped mirror plate for predefining the neutral tilt positions around the two tilt axes of the respective individual mirror is possible here as well. A combination of firstly a wedge-shaped mirror plate and secondly a wedge-shaped substrate body of the respective individual mirror is also possible, for example for decoupling the predefinition of the neutral tilt position of the individual mirror around the two tilt axes. The neutral tilt position around one of the two tilt axes can then be predefined by way of a wedge shape of the substrate body and the neutral tilt position around the other of the two tilt axes can then be predefined by way of a wedge shape of the mirror plate.

Configurations of the facet mirror assembly have proved worthwhile for a field facet mirror, a pupil facet mirror or a specular reflector.

The features of a related illumination optical unit, a related optical system, a related projection exposure apparatus, a related production method for a microstructured or nanostructured component, and such a microstructured or nanostructured component produced can thereby correspond to those which have already been explained above with reference to the facet mirror assembly. The illumination optical unit can be part of an illumination system to which a light source, for example an EUV light source, additionally belongs as well.

The component produced can be a semiconductor element, especially a microchip, in particular a memory chip.

### BRIEF DESCRIPTION OF THE DRAWINGS

At least one exemplary embodiment of the disclosure is described hereinafter with reference to the drawings, in which:

FIG. 1 schematically shows a meridional section of a projection exposure apparatus for EUV projection lithography;

FIG. 2 schematically shows a transmission-implemented using an illumination optical unit of the projection exposure apparatus according to FIG. 1—of partial fields predefined by adjacently arranged first facets of a first facet mirror of a facet mirror assembly of the illumination optical unit into partial sections of an object field of a downstream imaging optical unit of the projection exposure apparatus, via a transmission optical unit comprising a further facet mirror and a transfer mirror;

FIG. 3 shows a basic construction of an individual mirror of the facet mirror assembly in a cross section with the sectional plane perpendicular to a reflection surface;

FIG. 4 shows one embodiment of an arrangement of individual mirrors according to FIG. 3 with individually different neutral tilt positions of the individual mirrors relative to a carrying body of the facet mirror assembly for the individual mirrors, wherein the individual neutral tilt positions are predefined by corresponding wedge shapes of substrate bodies of the individual mirrors;

FIG. 5 shows a further embodiment of a group of individual mirrors for one embodiment of the facet mirror assembly, wherein the individual mirrors have the same neutral tilt position, which is predefined by way of a wedge shape of a common substrate body of the individual mirrors;

FIG. 6 shows a graphical rendering of a total tilt angle range of the individual mirrors of one embodiment of the facet mirror assembly including respective individual mirror tilt angle ranges, in one tilt axis dimension; and

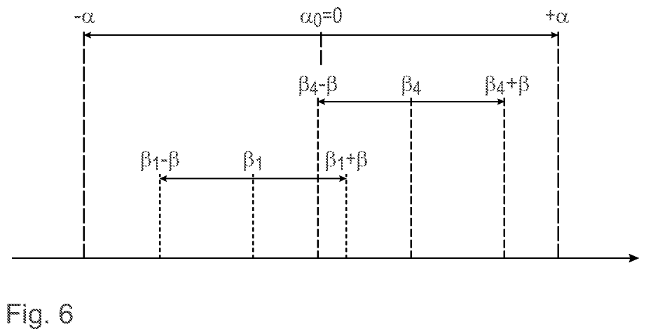

FIG. 7 shows a graphical rendering of a total tilt angle range of the individual mirrors of one embodiment of the facet mirror assembly including respective individual mirror tilt angle ranges, in two tilt axis dimensions.

### DETAILED DESCRIPTION

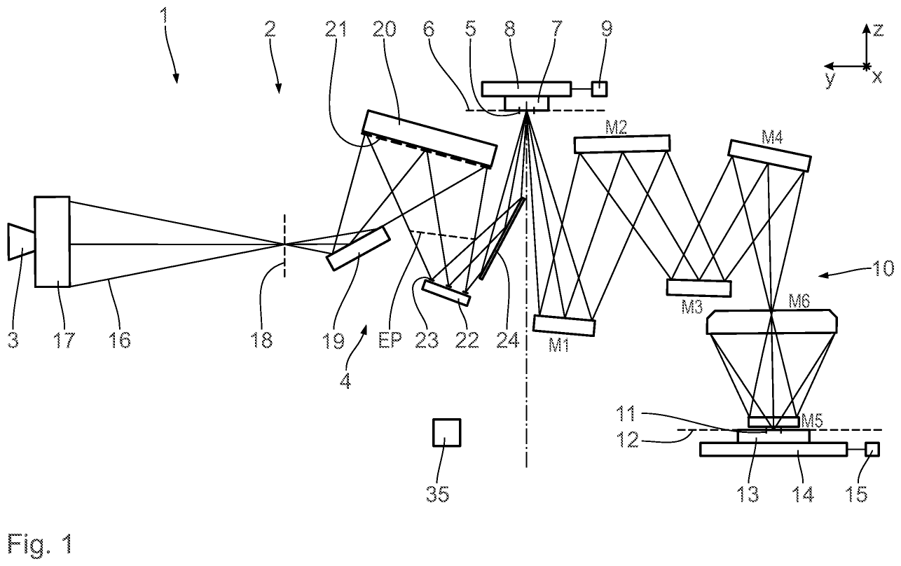

Hereinafter, the essential constituent parts of a microlithographic projection exposure apparatus 1 are described first by way of example with reference to FIG. 1. The description of the basic setup of the projection exposure apparatus 1 and the constituent parts thereof should be understood here to be non-limiting.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

The object field 5 is embodied in arcuate fashion. The object field 5 can be embodied in partial-ring-shaped fashion.

A reticle 7 arranged in the object field 5 is exposed. The reticle 7 is held by a reticle holder 8. The reticle holder 8 is displaceable by way of a reticle displacement drive 9, in particular in a scanning direction.

For explanation purposes, a Cartesian xyz-coordinate system is depicted in FIG. 1. The x-direction runs perpendicularly to the plane of the drawing into the latter. The y-direction runs horizontally and the z-direction runs vertically. The scanning direction runs along the y-direction in FIG. 1. The z-direction runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular along the y-direction. The displacement, firstly, of the reticle 7 by way of the reticle displacement drive 9 and, secondly, of the wafer 13 by way of the wafer displacement drive 15 can be implemented so as to be synchronized with one another.

The radiation source 3 is an EUV radiation source. The radiation source 3 emits, in particular, EUV radiation 16, which is also referred to below as used radiation, illumination radiation, or illumination light or imaging light. In particular, the used radiation has a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 can be a free electron laser (FEL).

The illumination radiation 16 emanating from the radiation source 3 is focused by a collector 17. The collector 17 can be a collector with one or with a plurality of ellipsoidal and/or hyperboloidal reflection surfaces. The illumination radiation 16 can be incident on the at least one reflection surface of the collector 17 with grazing incidence (GI), i.e. at angles of incidence of greater than 45°, or with normal incidence (NI), i.e. at angles of incidence of less than 45°. The collector 17 can be structured and/or coated firstly to optimize its reflectivity for the used radiation and secondly to suppress extraneous light. Together with the light source 3, the collector 17 can form a source-collector module.

Downstream of the collector 17, the illumination radiation 16 propagates through an intermediate focus in an intermediate focal plane 18. The intermediate focal plane 18 can represent a separation between a radiation source module, comprising the radiation source 3 and the collector 17, and the illumination optical unit 4.

The illumination optical unit 4 comprises a deflection mirror 19 and, disposed downstream thereof in the beam path, a first facet mirror 20 in the form of a facet mirror assembly, which will be explained in even greater detail below.

The deflection mirror 19 can be a plane deflection mirror or, alternatively, a mirror with a beam-influencing effect that goes beyond the purely deflecting effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 that is optically conjugate to the object plane 6 as a field plane, the facet mirror is also referred to as a field facet mirror. The first facet mirror 20 comprises a multiplicity of individual first facets 21, which are also referred to below as field facets. FIG. 1 illustrates only some of the facets 21 by way of example.

The first facet mirror 20 is located in a far field of the illumination light 16. The far field can be located approximately in a Fourier-conjugate plane to the light or radiation source 3.

The first facets 21 can be embodied as macroscopic facets, in particular as rectangular facets or as facets with an arcuate edge contour or an edge contour of part of a circle. The first facets 21 can be embodied as plane facets or alternatively as convexly or concavely curved facets. The first facets 21 are individually tiltable with the aid of assigned actuators.

As known for example from DE 10 2008 009 600 A1, the first facets 21 themselves can also be composed in each case of a multiplicity of individual mirrors, in particular a mutiplicity of micromirrors. The first facet mirror 20 can be configured in particular as a microelectromechanical system (MEMS system). For details, reference is made to DE 10 2008 009 600 A1.

Between the collector 17 and the deflection mirror 19, the illumination radiation 16 travels horizontally, i.e. along the y-direction.

In the beam path of the illumination optical unit 4, a second or further facet mirror 22 is disposed downstream of the first facet mirror 20. The second facet mirror 22 is located at a distance from an entrance pupil plane EP of the downstream projection optical unit 10, the entrance pupil plane being illustrated by way of example between the two facet mirrors 20, 22 in FIG. 1. The entrance pupil EP is the entrance-side image of the aperture-restricting stop of the projection optical unit 10. Alternatively, the second facet mirror can also be arranged in this entrance pupil EP or in the region thereof and is then referred to as a pupil facet mirror, which jointly with the field facet mirror 20 forms an illumination optical unit in the manner of a fly's eye condenser.

The entrance pupil plane EP of the projection optical unit 10 can be arranged upstream or downstream of the second facet mirror 22 in the beam path of the illumination light 16 in the case where the second facet mirror 22 is arranged at a distance from the entrance pupil plane EP. A distance between the entrance pupil plane and an arrangement plane of the second facet mirror 22 is at least 5% of a distance between the two facet mirrors 20, 22.

In the case where the second facet mirror 22 is arranged at a distance from the entrance pupil plane EP, the combination of the first facet mirror 20 and the second facet mirror 22 is also referred to as a specular reflector. Specular reflectors are known in principle from U.S. Pat. No. 9,977,335 or US 2006/0132747 A1, EP 1 614 008 B1, and U.S. Pat. No. 6,573,978.

The second facet mirror 22 comprises a plurality of second facets 23, which are also referred to as specular facets in the case of the embodiment as a specular reflector. The illumination optical unit 4 consequently forms a doubly faceted system.

The second facets 23 can likewise be macroscopic facets, which can, for example, have a round, rectangular or else hexagonal boundary, or alternatively be facets composed of individual mirrors or micromirrors. In this regard, reference is likewise made to DE 10 2008 009 600 A1.

The second facets 23 can have plane reflection surfaces or, alternatively, convexly or concavely curved reflection surfaces. The second facets 23 are individually tiltable with the aid of assigned actuators. In an alternative embodiment of the illumination optical unit, the second facets can also be designed as non-tiltable facets.

A transfer mirror 24 contributing to imaging the first facets 21 into the object field 5 is arranged in the beam path between the second facet mirror 22 and the object field 5. The transfer mirror 24 is embodied as a grazing incidence mirror (GI mirror). A smallest angle of incidence of the illumination light 16 on the transfer mirror 24 is greater than 45°, and can be greater than 60°, can be greater than 65°, can be greater than 70°, can be greater than 75° and can also be even greater. Such a transfer mirror 24 is not mandatory, and so after reflection at the second facets 23 of the second facet mirror 22 the illumination light 3 can also be guided directly toward the object field 5 in particular without further mirror reflection.

In the embodiment shown in FIG. 1, the illumination optical unit 4 has exactly four mirrors downstream of the collector 17, specifically the deflection mirror 19, the field facet mirror 20, the further facet mirror 22 and the transfer mirror 24. Depending on the embodiment of the illumination optical unit 4, the deflection mirror 19 can also be omitted, with the result that the first facet mirror 20 is the first beam-guiding component for the illumination light 16 downstream of the intermediate focal plane 18. A reflection surface of the transfer mirror 24 deviates from a plane surface, i.e. it does not extend in planar fashion but rather in curved fashion.

The transfer mirror 24 has a beam-shaping effect on the overall beam of the illumination light 16. Depending on its embodiment, the transfer mirror 24 has an imaging effect with an imaging factor that has a magnifying or, alternatively, size-reducing effect. An imaging factor of less than 1 describes a size-reducing imaging factor below. An imaging factor of greater than 1 describes a magnifying imaging factor.

In yet another alternative, the imaging factor can be 1, or the transfer mirror 24 can bring about imaging with imaging factors that differ firstly in the x-direction and secondly in the y-direction. The imaging factor of the transfer mirror 24 can have a value ranging between 0.1 and 10 in the x-direction and/or in the y-direction. In particular, the imaging factor can lie in the range between 0.125 and 8, can be between 0.25 and 4, can be between 0.33 and 3, can be between 0.5 and 2, and can also be between 0.75 and 1.25 or else between 0.9 and 1.1.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve, or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and can be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction between a y-coordinate of a centre of the object field 5 and a y-coordinate of the centre of the image field 11. This object-image offset in the y-direction can be of approximately the same magnitude as a z-distance between the object plane 6 and the image plane 12.

In particular, the projection optical unit 10 can have an anamorphic configuration. In particular, it has different imaging scales bₓ, b_{y} in the x- and y-directions. The two imaging scales bₓ, b_{y} of the projection optical unit 10 can be at (bₓ, b_{y})=(+/−0.25, +/−0.125). A positive imaging scale b means imaging without an image inversion. A negative sign for the imaging scale b means imaging with an image inversion.

The projection optical unit 10 consequently leads to a reduction in size with a ratio of 4:1 in the x-direction, i.e. in a direction perpendicular to the scanning direction.

The projection optical unit 10 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 5 and the image field 11 can be the same or can differ depending on the embodiment of the projection optical unit 10. Examples of projection optical units with different numbers of such intermediate images in the x- and y-directions are known from US 2018/0074303 A1.

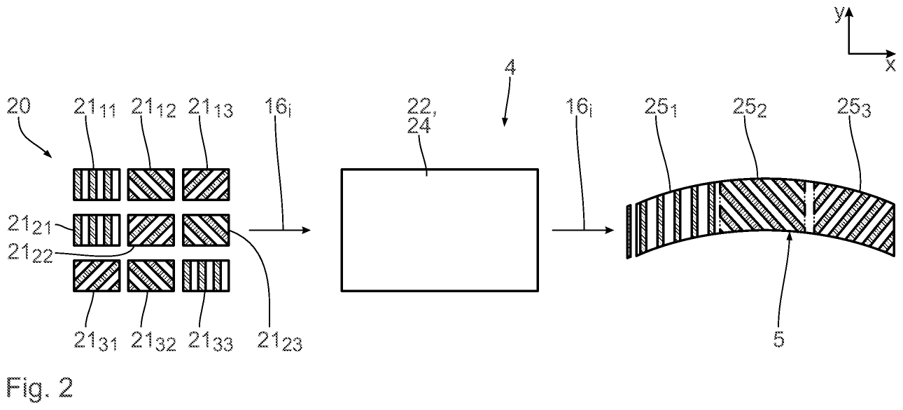

The first facets 21 of the first facet mirror 20, given a corresponding embodiment of the illumination optical unit 4, can serve to predefine partial fields which are transferred into partial sections 25ᵢ of the object field 5 by the illumination optical unit 4 (cf. FIG. 2). This transfer can be imaging. The respective second facet 23, which can in turn comprise a plurality of individual mirrors and which is used on the second facet mirror 22 to guide a respective component beam 16ᵢ, is also referred to as a virtual partial field facet 23.

FIG. 2 clarifies this transfer by the first facets 21 into the partial sections 25 of the object field 5 on the basis of a total of nine first facets 21ᵢⱼ, which are arranged in three rows (i=1, 2, 3) and in three columns (j=1, 2, 3). Accordingly, FIG. 2 depicts a section of the first facet mirror 20 with a total of nine first facets 21ᵢⱼ. In fact, the number of first facets 21 of the first facet mirror 20 is significantly larger and can be in the range of several 100, for example.

Each first facet 21 can consist of a contiguous macroscopic reflection surface. Alternatively, each first facet 21 can consist of a plurality of adjacent individual mirrors or micromirrors.

Component beams 16ᵢ of an overall beam of the illumination light 16 are reflected in each case by the first facets 21ᵢⱼ, and the partial fields predefined by the first facets 21ᵢⱼ are thus transferred into the partial sections 25₁, 25₂, 25₃ of the object field 5. The transfer optical unit used for this purpose, which is formed by the second facet mirror 22 and the transfer mirror 24, is only depicted schematically in FIG. 2.

The first facets 21ᵢⱼ can be embodied with a rectangular reflection surface boundary such that the partial fields predefined by way of the first facets 21ᵢⱼ are rectangular.

Component beams 16ᵢ which are reflected by the first facets 21₁₁, 21₂₁ and 21₃₃ are transferred in overlaid fashion into the partial section 25₁ depicted to the left of the object field 5 in FIG. 2 by the transmission optical unit 22, 24. Component beams 16; which are reflected by the first facets 21₁₂, 21₂₃ and 21₃₂ are transferred into the partial section 25₂ depicted in the center of the object field 5 in FIG. 2 via the transmission optical unit 22, 24. Component beams 16; which are reflected by the first facets 21₁₃, 21₂₂ and 21₃₁ are transferred into the partial section 25₃ depicted to the right of the object field 5 in FIG. 2 via the transfer optical unit 22, 24.

Transversely to the object displacement direction y, i.e. along the x-direction, the partial sections 25ᵢ have an extent amounting to one third of an x-extent of the object field. Depending on the embodiment of the illumination optical unit 4, this x-extent of the partial sections can be no more than 50%, can be no more than 40%, can be no more than 30%, can be no more than 25%, can be no more than 10%, and can for example be 5% or optionally be even smaller. This x-extent of the partial sections 25 is regularly greater than 1% of the x-extent of the object field 5.

The partial sections 25 have an extent over the entire object field 5 along the object displacement direction y. Alternatively, it is possible that a plurality of adjacent partial fields are also present along the y-direction, for example two, three or even more such partial fields.

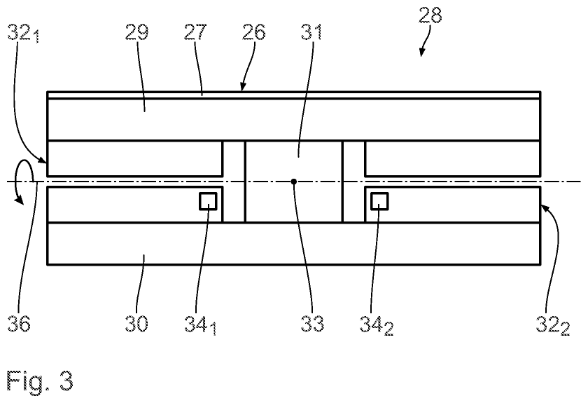

FIG. 3 shows a basic construction of one of the mirrors of the first facet mirror 20 and/or of the second facet mirror 22 in the cross section perpendicular to a reflection surface 26 having a reflective coating 27. This mirror can be a first facet 21 of the first facet mirror 20 and/or a second facet 23 of the second facet mirror 22. Alternatively, the individual mirror 28 in FIG. 3 can be an individual mirror or micromirror which, together with further individual mirrors of this type, is part of a first facet 21 or second facet 23 of this type, such as has already been explained above. The construction according to FIG. 3 will be explained on the basis of an individual mirror 28 of this type.

The individual mirror 28 has a mirror plate 29, on which the reflective coating 27 is applied. Furthermore, the individual mirror 28 has a substrate body 30. The mirror plate 29 and the substrate body 30 are mechanically connected to one another by way of a suspension 31. In one embodiment of the individual mirror 28 the mirror plate 29, the substrate body 30 and the suspension 31 are constituent parts of a monolithic body, i.e. merge integrally into one another.

The individual mirror 28 furthermore has tilt actuators 32₁, 32₂ arranged in each case between the mirror plate 29 and the substrate body 30. The tilt actuators 32₁, 32₂ are arranged on both sides of the suspension 31. The tilt actuators 32₁, 32₂ are embodied in capacitive fashion, i.e. each have a mirror-plate-side electrode and a substrate-side electrode, with an air gap between these electrodes. The tilt actuators 32₁, 32₂ make it possible to tilt the mirror plate 29 relative to the substrate body 30 in the region of the suspension 31 about a tilt axis 33, which is perpendicular to the plane of the drawing in FIG. 3.

The tilt actuators 32₁, 32₂ can be assigned a respective sensor unit 34₁, 34₂. A tilt angle of the mirror plate 29 with respect to the substrate body 30 can be measured via the sensor units 34₁, 34₂. The sensor units 34ᵢ are signal-connected to a central control/regulating device 35, illustrated schematically in FIG. 1.

In order to tilt the mirror plate 29 relative to the substrate body 30 about a further tilt axis 36, which is perpendicular to the tilt axis 33 and lies in the plane of the drawing in FIG. 3, the individual mirror 28 has two further tilt actuators 32ᵢ, which are not illustrated in FIG. 3 and are arranged respectively in front of and behind the plane of the drawing in FIG. 3 such that the suspension 31 in turn lies between these two further tilt actuators 32ᵢ. The two tilt axes 33, 36 span a plane to which the reflection surface 26 is arranged parallel in a neutral tilt position illustrated in FIG. 3.

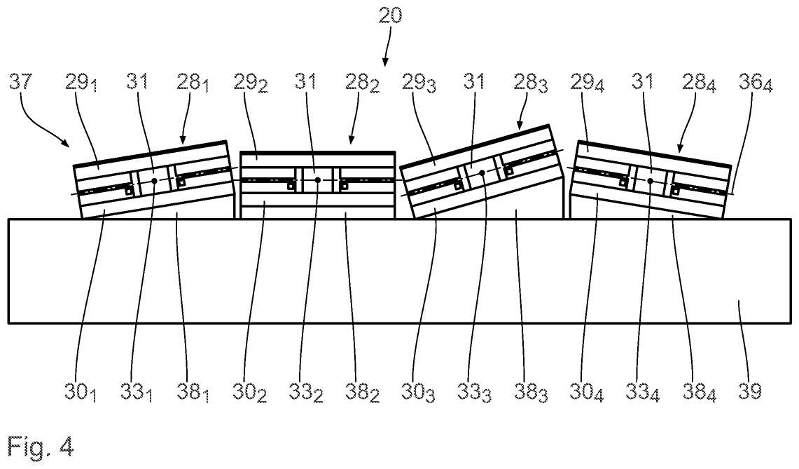

FIG. 4 shows an embodiment variant for a facet mirror assembly 37 comprising a total of four individual mirrors 28₁, 28₂, 28₃, 28₄ in the manner of the individual mirror 28 from FIG. 3. This facet mirror assembly 37 can be used as part of the facet mirror 20 and/or as part of the facet mirror 22. In this case, the individual mirrors 28ᵢ can be individual mirrors which jointly construct a virtual facet in particular of the first facet mirror 20, or else can be the facets altogether, in particular the first facet 21 of the first facet mirror 20.

The individual mirrors 28ᵢ can be individually tilted, via their assigned tilt actuators 32ᵢ, about the respective tilt axes 33, 36 within an individual mirror tilt angle range around the neutral tilt position—illustrated in each case in FIG. 4—between a maximum angle and a minimum angle. For one tilt angle dimension, namely for the tilt about the tilt axes 33ᵢ of the respective individual mirrors 28ᵢ perpendicular to the plane of the drawing in FIG. 4, this is represented for two different neutral tilt positions β₁, for example of the individual mirror 28₁ in FIG. 4, and β₄, for example of the individual mirror 28₄ in FIG. 4. The individual mirror 28₁ is tiltable around its neutral tilt position β₁ in a tilt angle range around the tilt axis 33₁ between a minimum angle β₁−β and a maximum angle β₁+β. The individual mirror 28₄ is tiltable around its neutral tilt position β₄ between a minimum angle β₄−β and a maximum angle β₄+β. The two neutral tilt positions β₁ and β₄ differ in terms of the absolute tilt angle about the tilt axis 33₁ and respectively 33₄. The two tilt angle ranges [β₁−β; β₁+β] and [β₄−β; β₄+β] lie within a total tilt angle range [−α; +α] around a mean value α₀ defined as α₀=0.

The different neutral tilt positions βᵢ of the individual mirrors 28ᵢ are attained by way of a corresponding wedge shape of a wedge connecting section 38₁, 38₂, 38₃, 38₄ of the respective substrate body 30₁ to 30₄ of the individual mirror 28₁ to 28₄. Via the respective wedge connecting section 38ᵢ, the individual mirror 28ᵢ is connected to a carrier body 39 of the facet mirror assembly 37. In order to predefine the neutral tilt positions βᵢ around the two tilt axes 38ᵢ and 36ᵢ, the wedge connecting sections 38ᵢ can be of two-dimensionally wedge-shaped design, such that a wedge angle of these wedge connecting sections 38ᵢ is present not only in the plane of the drawing in FIG. 4 but also in a plane of the drawing which is perpendicular thereto and to which the tilt axes 36ᵢ are perpendicular.

For the neutral tilt positions βᵢ of the individual mirrors 28ᵢ in the arrangement according to FIG. 4, the applicable ratio is β₃<β₁<β₂ (=0)<β₄.

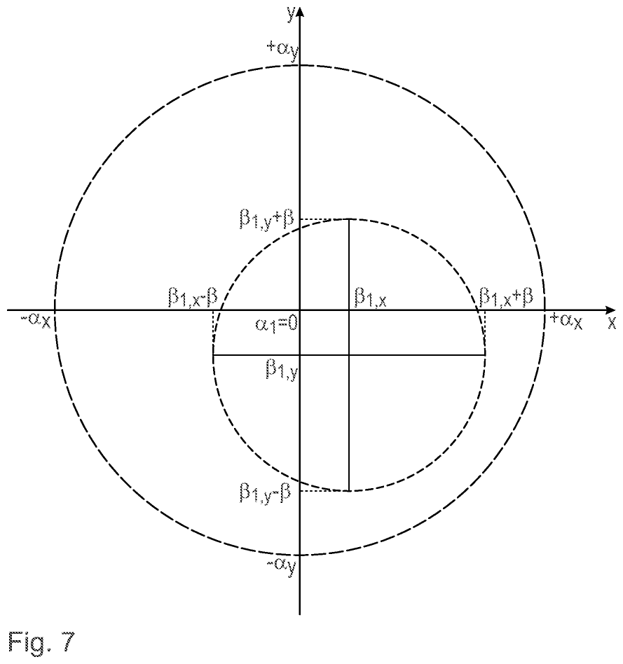

FIG. 7 schematically shows for one of the mirrors 28ᵢ the location of the individual mirror tilt angle range in the two tilt angle dimensions x and y around the neutral tilt position β_{1,x}, β_{1,y} within the total tilt angle range [−α_{x/y}; +α_{x/y}]. It is assumed here that an individual mirror tilt angle range βᵢ±β is of the same magnitude for both tilt angle dimensions x (corresponding to tilt axis 33ᵢ) and y (corresponding to tilt axis 36ᵢ). Accordingly, it is assumed that the total tilt angle range [−_{x/x}; +α_{x/y}] is also of the same magnitude in tilt angle dimensions, which results in circular representations for the individual tilt angle range around the neutral tilt position β_{1,x}; β_{1,y} and for the total tilt angle range around the coordinate origin (α₀=0) in FIG. 7.

In the case of the embodiment according to FIG. 4, each of the individual mirrors 28ᵢ has an individual neutral tilt position βᵢ or β_{1,x}; β_{i,y}.

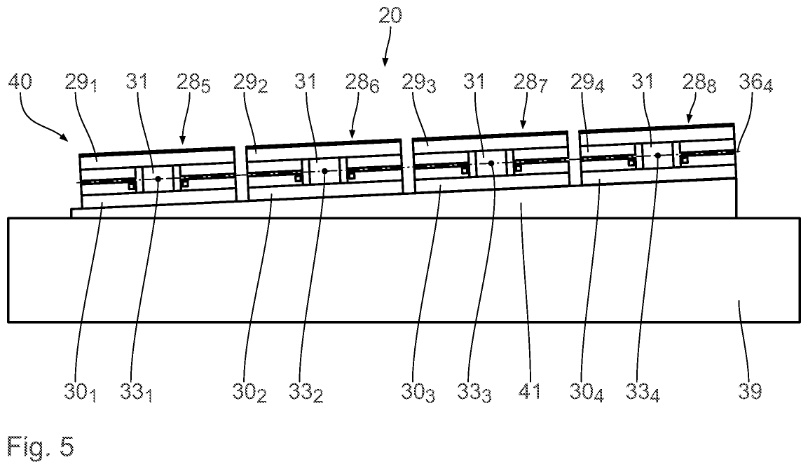

Alternatively or additionally, the facet mirror assembly can have in sections a plurality of individual mirrors 28ᵢ each having the same tilt angle value for the neutral tilt position βᵢ. This is explained below on the basis of the facet mirror assembly section 40 according to FIG. 5. The facet mirror assembly section 40 has four individual mirrors 28₅, 28₆, 28₇, 28₈, the basic construction of which once again corresponds to that of the individual mirror 28 according to FIG. 3.

In the case of the facet mirror assembly section 40, these individual mirrors 28₅ to 28₈ are connected to the carrier body 39 of the facet assembly via a common wedge connecting section 41. A wedge angle of the wedge connecting section 41 then predefines the neutral tilt positions β₅=β₆=β₇=β₈ of the individual mirrors 28₅ to 28₈ of the facet mirror assembly section 40.

The individual mirrors 28₅ to 28₈ predefine a group of individual mirrors 28ᵢ each having the same group neutral tilt position βᵢ.

The facet mirror assembly 20 has in particular a plurality of such facet mirror assembly sections 40 having different wedge connecting sections 41, which predefine different wedge angles and thus different neutral tilt positions βᵢ of the individual mirrors 28ᵢ of the respective facet mirror assembly section 40.

The total tilt angle range [−α; +α] is greater than the individual mirror tilt angle range [βᵢ−β; βᵢ+β]. A ratio between the total tilt angle range and the respective individual mirror tilt angle range is between 1.1 and 100, in particular in the range of between 1.1 and 10, for example between 1.1 and 3, and can be in particular of the order of 2.

In order to satisfy the condition that the respective individual mirror tilt angle range lies within the total tilt angle range, the neutral tilt positions βᵢ of the individual mirrors 28ᵢ lie in a range [α₀−α+β; α₀+α−β], which is satisfied for both dimensions x and y.

A tilt angle variation firstly around the tilt axes 33ᵢ may differ from a tilt angle variation around the tilt axes 36ᵢ, and so besides circular tilt angle ranges, as in FIG. 7, elliptic or oval tilt angle ranges may result as well. A ratio between the tilt angle variations around the respective neutral tilt position in the two tilt angle dimensions x and y may be in the range of between 1 and 10, in particular in the range of between 1 and 2.

In the case of an embodiment that is not illustrated in the drawing, the respective neutral tilt position βᵢ of the respective individual mirror 28ᵢ is predefined by way of a corresponding wedge shape of the mirror plate 29ᵢ of the respective individual mirror 28ᵢ. The mirror plate 29ᵢ then additionally has the function of a wedge connecting section in line with the function which has been explained above in association with the wedge connecting section 38ᵢ or respectively 41.

In the case of a further embodiment, likewise not illustrated, of respective facet mirror assembly sections in the manner of the facet mirror assembly sections 37 according to FIG. 4 and 40 according to FIG. 5, provision can be made of a combination of wedge connecting sections 38 and respectively 41 for predefining the neutral tilt positions βᵢ in one tilt angle dimension and a wedge-shaped mirror plate 29ᵢ for predefining the neutral tilt position βᵢ in the other tilt angle dimension. In this case, it is possible to decouple the predefinition of the neutral tilt position around the two tilt axes 33ᵢ and respectively 36ᵢ with regard to the wedge body responsible therefor. The neutral tilt position around one of these tilt axes, for example around the tilt axis 33, can be predefined by way of the wedge shape of the substrate body and the neutral tilt position βᵢ around the other tilt axis, for example the tilt axis 38, can be predefined by way of the wedge shape of the mirror plate 29.

In order to produce a microstructured component, in particular a highly integrated semiconductor component, for example a memory chip, with the aid of the projection exposure apparatus 1, firstly the reticle 7 and the wafer 13 are provided. Subsequently, a structure on the reticle 7 is projected onto a light-sensitive layer on the wafer 13 using the projection optical unit of the projection exposure apparatus 1. By developing the light-sensitive layer, a microstructure is then produced on the wafer 13 and the microstructured or nanostructured component is produced therefrom.

What is claimed is:

1. A facet mirror assembly, comprising:
in a plurality of individual mirrors, each mirror comprising a reflection surface;
a plurality of tilt actuators;
a carrier body configured to carry the plurality of individual mirrors,
wherein:
for each individual mirror, tilt actuators assigned to the individual mirror are configured to tilt the reflection surface of the individual mirror about a tilt axis around a neutral tilt position in a tilt angle range between a maximum angle and a minimum angle;
for each individual mirror, the individual mirror has at least two different neutral tilt positions in a range around a mean value of a total tilt angle range; and
the facet mirror assembly is a MEMS facet mirror assembly.

2. The facet mirror assembly of claim 1, wherein, for each individual mirror, tilt actuators assigned to the individual mirror are configured to tilt the reflection surface of the individual mirror about two tilt axes, in each case around a corresponding neutral tilt position in a corresponding tilt angle range between a corresponding maximum angle and a corresponding minimum angle.

3. The facet mirror assembly of claim 2, wherein, for each individual mirror and to define each tilt angle range, the individual mirror has at least two different neutral tilt positions, in each case in a range around a mean value of a corresponding total tilt angle range around the tilt axis.

4. The facet mirror assembly of claim 3, wherein the plurality of individual mirrors are configured as a plurality of groups, each group comprising facet mirrors having the same neutral tilt position.

5. The facet mirror assembly of claim 2, wherein the plurality of individual mirrors are configured as a plurality of groups, each group comprising facet mirrors having the same neutral tilt position.

6. The facet mirror assembly of claim 2, wherein a total tilt angle range is at least 1.1 times that of the individual mirror tilt angle range.

7. The facet mirror assembly of claim 2, wherein, for each individual mirror:
the individual mirror comprises a mirror plate and a substrate body; and
each tilt actuator assigned to the mirror is between the mirror plate and the substrate body.

8. The facet mirror assembly of claim 7, wherein, for each individual mirror and to define each tilt angle range, the individual mirror has at least two different neutral tilt positions, in each case in a range around a mean value of a corresponding total tilt angle range around the tilt axis.

9. The facet mirror assembly of claim 1, wherein the plurality of individual mirrors are configured as a plurality of groups, each group comprising facet mirrors having the same neutral tilt position.

10. The facet mirror assembly of claim 1, wherein a total tilt angle range is at least 1.1 times that of the individual mirror tilt angle range.

11. The facet mirror assembly of claim 1, wherein, for each individual mirror:
the individual mirror comprises a mirror plate and a substrate body; and
each tilt actuator assigned to the mirror is between the mirror plate and the substrate body.

12. The facet mirror body of claim 11, wherein, for each individual mirror, the neutral tilt position is defined by a wedge shape of a wedge connecting section of the substrate body.

13. The facet mirror body of claim 11, wherein, for each individual mirror, the neutral tilt position is defined by a wedge shape of the mirror plate.

14. The facet mirror assembly of claim 1, wherein the facet mirror assembly is a field facet mirror.

15. The facet mirror assembly of claim 1, wherein the facet mirror assembly is a pupil facet mirror.

16. The facet mirror assembly of claim 1, wherein the facet mirror assembly is a specular reflector.

17. An illumination optical unit configured to illuminate an object field with light from a light source, the illumination optical unit comprising:
a facet mirror comprising a facet mirror assembly according to claim 1,
wherein the illumination optical unit is a projection lithography illumination optical unit.

18. An optical system, comprising:
an illumination optical unit comprising a facet mirror assembly according to claim 1; and
a projection optical unit having an object field and an image field,
wherein:
the illumination is configured to illuminate the object field with light from a light source;
the projection optical unit is configured to image the object field into the image field; and
the optical system is a projection lithography optical system.

19. An apparatus, comprising:
a light source;
an illumination optical unit comprising a facet mirror assembly according to claim 1; and
a projection optical unit having an object field and an image field,
wherein:
the illumination is configured to illuminate the object field with light from the light source;
the projection optical unit is configured to image the object field into the image field; and
the apparatus is a projection exposure apparatus.

20. A method of using a projection exposure apparatus comprising an illumination optical unit and a projection optical unit, the method comprising:
using the illumination optical unit to illuminate a portion of an object in an object field; and
using the projection optical unit to project the illuminated object into an image field,
wherein the illumination optical unit comprises a facet mirror assembly according to claim 1.
